(19) United States
(12) Patent Application Publication
(10) Pub. No.: US 2025/0180999 A1
(43) Pub. Date: Jun. 5, 2025

(54) METHOD OF MANUFACTURING A SEMICONDUCTOR DEVICE AND APPARATUS FOR MANUFACTURING A SEMICONDUCTOR DEVICE

(71) Applicant: Taiwan Semiconductor Manufacturing Company, Ltd., Hsinchu (TW)

(72) Inventors: Hsieh-Yu WEI, Taoyuan City (TW); Yung-Yao LEE, Zhubei City (TW); Kuo-Hung CHAO, Hsinchu City (TW)

(73) Assignee: Taiwan Semiconductor Manufacturing Company, Ltd., Hsinchu (TW)

(21) Appl. No.: 18/530,098

(22) Filed: Dec. 5, 2023

(51) Int. Cl. G03F 7/00

(52) U.S. Cl. CPC G03F 7/70341; G03F 7/70808; G03F 7/70975

(57) ABSTRACT

Fluid pressure flowing through first main line in pressure compensator using first pressure sensor is measured. Fluid flows along first main line through pressure compensator to semiconductor device processing apparatus, through apparatus, then through compensator via second main line. First pressure sensor is attached to first pressure sensor line branching off first main line. Fluid pressure flowing through second main line is measured using second pressure sensor. Second pressure sensor is attached to second pressure sensor line branching off second main line. Pressure difference between fluid flowing through first and second main lines is determined. Fluid flow rate is adjusted when difference is greater than threshold amount. A first tank is attached to one of first or second main lines via a conduit, and second tank is attached to first or second pressure sensor line when first tank is attached to corresponding first or second main line via a conduit.

### BACKGROUND

As the semiconductor industry has progressed into nanometer technology process nodes in pursuit of higher device density, higher performance, and lower costs, challenges from both fabrication and design issues have resulted in the development of devices with smaller critical dimensions. The photolithography operation is critical to reducing the critical dimension. Immersion lithography has been developed to provide high speed patterning of features having reduced critical dimensions. Multiple photolithographic exposures are provided over the same portion of a semiconductor wafer to form multiple patterned layers of semiconductor devices. Precise overlay of the photolithographic exposures for forming the multiple patterned layers is necessary for the formation of smaller, high density semiconductor devices.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a schematic illustration of a photolithography apparatus according to some embodiments of the disclosure.

FIG. 2 is a schematic plan view of a portion of a photolithography apparatus according to some embodiments of the disclosure.

FIG. 3 is a schematic plan view of a portion of a photolithography apparatus according to some embodiments of the disclosure.

FIGS. 4A and 4B are schematic illustrations of pressure compensators according to some embodiments of the disclosure.

FIG. 5 is a schematic illustration of a pressure compensator according to some embodiments of the disclosure.

FIG. 6 shows a flowchart of a method of manufacturing a semiconductor device according to some embodiments of the disclosure.

FIG. 7 shows a flowchart of a method of manufacturing a semiconductor device according to some embodiments of the disclosure.

FIG. 8 shows a flowchart of a method of manufacturing a semiconductor device according to some embodiments of the disclosure.

FIG. 9A and FIG. 9B are diagrams of a controller according to some embodiments of the disclosure.

FIG. 10A shows the difference between the standard deviation of the incoming coolant fluid pressure and the standard deviation of the outgoing cooling fluid pressure in the pressure compensator according to some embodiments of the disclosure. FIG. 10B shows the variation in the pressure of the inflowing coolant in a pressure compensator in some embodiments. FIG. 10C shows the variation in the pressure of the outflowing coolant in a pressure compensator in some embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanied drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in/between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. Materials, configurations, dimensions, processes and/or operations same as or similar to those described with one embodiment may be employed in the other embodiments and the detailed explanation may be omitted.

Immersion lithography has been implemented to take advantage of the process technology's capability for much improved resolution. Immersion lithography features the use of a liquid medium to fill the entire gap between the last objective lens element of the light projection system and the semiconductor wafer (substrate) surface during the light exposure operations of the photoresist pattern printing process. The liquid medium used as the immersion lens provides an improved index of refraction for the exposing light, thus improving the resolution capability of the lithographic system. This is represented by the Rayleigh Resolution formula, R=k₁λ/N.A., where R (feature size resolution) is dependent upon k₁ (certain process constants), λ (wavelength of the transmitted light), and the N.A. (numerical aperture of the light projection system). It is noted that N.A. is also a function of the index of refraction where N.A.=n sin θ. Variable n is the index of refraction of the liquid medium between the objective lens and the wafer substrate, and θ is the acceptance angle of the lens for a transmitted light.

As the index of refraction (n) becomes higher for a fixed acceptance angle, the numerical aperture (N.A.) of the projection system becomes larger thus providing a lower R value, i.e. a higher resolution. In some embodiments, the immersion lithographic system uses de-ionized water as the immersion fluid between an objective lens and the wafer substrate. At one of the wavelengths, for example 193 nm, de-ionized water at 20° C. has an index of refraction of approximately 1.44 versus air, which has an index of refraction at approximately 1.00. Thus, immersion lithographic systems offer a significant improvement to the resolution of the photolithography processes.

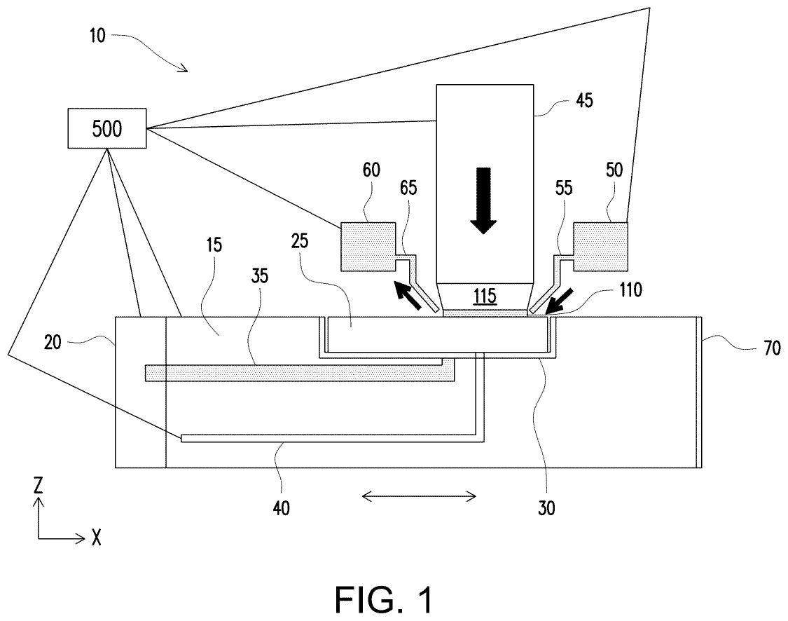

FIG. 1 is a schematic cross-sectional illustration of an immersion photolithography apparatus 10 according to some embodiments of the disclosure. The apparatus includes a movable wafer stage 15 incorporated with vacuum channels 40 for holding and fixing a photoresist-coated wafer 25 onto a wafer table 30 on the wafer stage 15. An immersion fluid 110 is located on top of the photoresist-coated wafer 25 displacing the entire volume of space between the wafer and the last objective lens element 115 of the photolithography apparatus's light projection system 45. The immersion fluid 110 is in direct contact with both the top surface of the photoresist coated wafer 25 and the lower surface of the objective lens element 115.

The immersion fluid 110 is any suitable liquid having an index of refraction greater than 1. In some embodiments, the immersion fluid 110 is water, an aqueous solution, or a non-aqueous liquid or solution. In some embodiments, the non-aqueous liquid includes hydrocarbons and derivatives thereof, including but not limited to, cyclic alkanes and acyclic alkanes (e.g. dodecane, hexane, pentane, hexadecane. cyclohexane, bicyclohexane, tricyclohexanes. decahydronaphthalene, and cyclopentane; fluorinated (partially or fully) hydrocarbons and derivatives thereof (e.g., perfluorocyclohexane and perfluorodecalin); SF₅-functionalized hydrocarbons; halocarbons (e.g. Freon 113); ethers (e.g. ethyl ether (Et₂O), tetrahydrofuran (THF), ethylene glycol and derivatives thereof, monomethyl ether, or 2-methoxyethyl ether (diglyme)), and esters and derivatives thereof (e.g. sodium octanoate and sodium perfluorooctanoate). Still further exemplary fluids include lactates; pyruvates; diols; ketones, including, acetone, cyclohexanone. N-methyl pyrrolidone (NMP), and methyl ethyl ketone. Other exemplary non-aqueous fluids include amides such as, but not limited to, dimethylformamide, dimethylacetamide, acetic acid anhydride, propionic acid anhydride, and the like. Exemplary non-aqueous fluids can include, but are not limited to, sulfur-containing compounds such as mercaptans (e.g., lauryl mercaptan), sulfones (e.g., dimethyl sulfone, diphenyl sulfone, sulfoxides (e.g., dimethyl sulfoxide). In addition, the non-aqueous fluids include alcohols such as, propylene glycol propyl ether (PGPE), methanol, tetrahydrofurfuryl alcohol, 1-methylcyclohexanol, cyclohexanol, 2-methylcyclohexanol, adamantanemethanol, cyclopentanol, dimethyl-3-heptanol, dimethyl-4-heptanol, dodecanol, oleyl alcohol, pentanol, 1,5-pentanediol, 1,6-hexanediol, 1,4-butanediol, 1,2-propylene glycol, 1,3-propylene glycol, I-dodecanol, cyclooctane, ethanol, 3-heptanol, 2-methyl-1-pentanol, 5-methyl-2-hexanol, cis-2-methylcyclohexanol, 3-hexanol, 2-heptanol, 2-hexanol, 2,3-dimethyl-3-pentanol, propylene glycol methyl ether acetate (PGMEA), ethylene glycol and derivatives thereof, polyethylene glycol and derivatives thereof. isopropyl alcohol (IPA), n-butyl ether, propylene glycol n-butyl ether (PGBE), 1-butoxy-2-propanol, 2-methyl-3-pentanol, 2-methoxyethyl acetate, 2-butoxyethanol, 2-ethoxyethyl acetoacetate, 1-pentanol, propylene glycol methyl ether, 3,6-dimethyl-3,6-octanol, maltose, sorbitol. mannitol, super, fully. and partially hydrolyzed poly(vinyl)alcohol, 1,3-butanediol, glycerol and derivatives thereof such as thioglycerol. The immersion fluid may include an acid such as, sulfuric acid, lactic acid, octanoate acid, polyphosphoric acid, phosphoric acid, hexafluorophosphoric acid, tartaric acid, methane sulfonic acid, trifluoromethane sulfonic acid, dichloroacetic acid, propionic acid, and citric acid. The non-aqueous fluid may include an ester, such as ethyl acetate. Other suitable non-aqueous fluids include a silicone oil. Other non-aqueous fluids include 1,4-dioxane, 1,3-dioxolane, ethylene carbonate, propylene carbonate, ethylene carbonate, propylene carbonate, and m-cresol. The non-aqueous fluids enumerated above may be used alone, in combination with one or more other non-aqueous fluids, or in combination with an aqueous fluid.

In some embodiments, the immersion fluid may comprise a mixture of at least one aqueous fluid and at least one non-aqueous fluid. In these embodiments, the immersion fluid may contain at least one non-aqueous fluid that is miscible in the aqueous fluid or is water miscible. The amount of non-aqueous fluid within the immersion fluid may range from about 1 to about 99%, or from about 1 to about 50% by weight with the balance of the carrier medium within the immersion fluid comprising an aqueous fluid. Examples of water-miscible non-aqueous fluids include, but are not limited to, methanol, ethanol, isopropyl alcohol, glycerol, ethylene glycol and derivatives thereof, polyethylene glycol and derivatives thereof, and THF.

There are two fluid reservoirs 50, 60 configured to deliver the immersion fluid to the region between the last objective lens element 115 and the photoresist-coated wafer 25. A fluid supply reservoir 50 supplies and injects the immersion fluid 110 through an immersion fluid supply line 55 into the area under the objective lens element 115. The injected immersion fluid 110 is either held by capillary forces in the immersion area or contained within a fixture (not shown) moving with the lens. A thickness of the immersion fluid 110 between the objective lens element 115 and the photoresist-coated wafer is between about 1 mm to about 2 mm. A fluid recovery reservoir 60 recovers the output immersion fluid flow from the area between the objective lens element 115 and the photoresist-coated wafer 25 via an immersion fluid recovery line 65. The downward arrow located over the light projection system 45 represents the direction of and the transmission of the pattern image-exposing actinic radiation through the last objective lens element 115 and through the immersion fluid 110 to the photoresist-coated wafer 25. During normal operation of the immersion lithography printing of the photoresist-coated wafer 25, the wafer stage 15 moves to position each exposure target area of the wafer under the fixed locations of the immersion fluid 110, the fluid reservoirs 50, 60, the objective lens element 115, and the pattern image-exposing radiation.

In immersion photolithography, the wafer stage 15 moves rapidly during the exposure operation. In some embodiments the wafer stage 15 scan speed is equal to or greater than 800 mm/s. The arrows below the wafer stage 15 illustrates the motion of the wafer stage 15 along the x axis. Heat is generated in the wafer stage 15 and wafer table 10 during the photolithographic exposure operations. The wafer stage 15 and wafer table 10 are cooled during the exposure by flowing or pulsing a coolant or cooling fluid through coolant or cooling fluid lines or conduits 35 in the wafer stage 15. The rapid motion of the wafer stage 15 may cause pressure shocks and pressure imbalances, resulting in a disturbance effect in the wafer stage 15. The pressure of the cooling fluid or coolant flowing through the wafer stage 15 is monitored by pressure sensors in a pressure compensator 20 attached to a side of the wafer stage 15 in some embodiments.

A controller 500 monitors and controls the motion and positioning of the wafer stage 15 in some embodiments. In some embodiments, the controller 500 monitors the pressure of the cooling fluid or coolant in the pressure compensator 20. The controller 500 also controls the application and release of a vacuum in the vacuum line 40 for securing or releasing a wafer in some embodiments. In some embodiments, the controller 500 controls the raising and lowering of wafer support pins (not shown) to receive wafers onto the wafer table 30 or release the wafers from the wafer table 30. The controller further controls the light projection system 45 and controls the exposure of the photoresist-coated wafer 25 to actinic radiation in some embodiments. Furthermore, in some embodiments, the controller monitors the immersion fluid level in the fluid reservoirs 50, 60 and controls the dispensing and recovery of the immersion fluid 110.

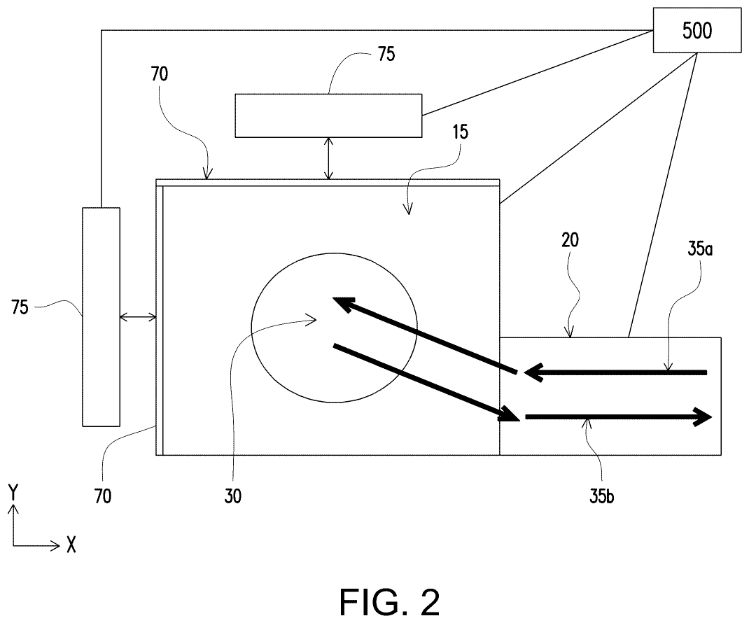

FIG. 2 is a schematic plan view of a portion of the photolithography apparatus according to some embodiments of the disclosure. As shown in FIG. 2, the controller 500 monitors the position and location of the wafer stage using interferometers 75 in some embodiments. The interferometers 75 use light reflected off mirrors 70 on the sides of the wafer stage 15 to accurately determine the location of the wafer stage 15. As shown in FIG. 2, the coolant or cooling fluid lines or conduits include an inflow line 35a where the coolant or cooling fluid flows from the pressure compensator 20 towards the wafer table 30 and an outflow line 35b line where the coolant or cooling fluid flows from the wafer table 30 towards the pressure compensator 20. In some embodiments, the coolant or cooling fluid, such as water, is stored in a reservoir (not shown), and is circulated through a heat exchanger (not shown) before circulating through the inflow line 35a in the pressure compensator 20.

In some embodiments, the coolant or cooling fluid is any suitable liquid, including water; a water/ethylene glycol mixture; or a perfluoro hydrocarbon-based liquid, such as perfluorohexane, perfluoro(2-butyl-tetrahydrofurane), perfluorotripentylamine, and a perfluoroketone.

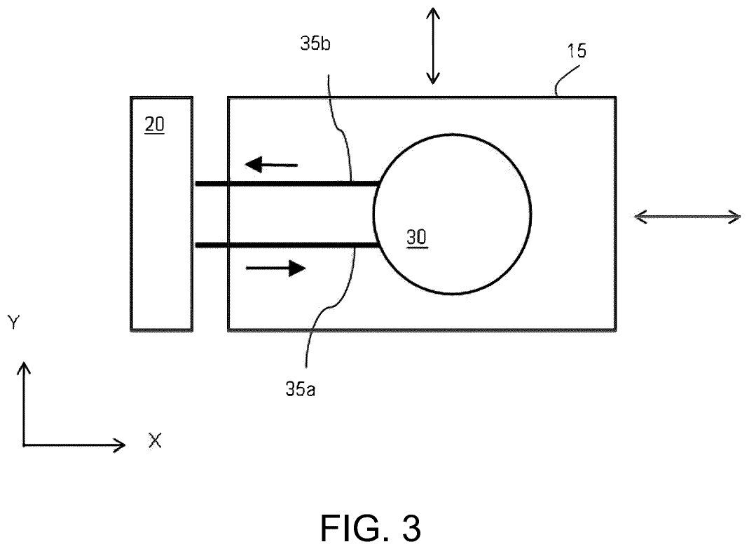

FIG. 3 is a schematic plan view of a portion of the photolithography apparatus according to some embodiments of the disclosure. In some embodiments, a cable slab (not shown) comprising a plurality of wires is connected to the wafer stage 15 via a connector in some embodiments. In some embodiments, one or more wires are connected to the controller 500 (not shown in FIG. 3), a power supply (not shown), motors (not shown) for moving the wafer stage, or the pressure compensator 20. As shown in FIG. 3, the coolant inflow line or conduit 35a runs from the pressure compensator 20, through the wafer stage 15, to the wafer table 30, and the coolant outflow line or conduit 35b runs from the wafer table 30, through the wafer stage 15 to the pressure compensator 20. The arrows show the directions of motion of the wafer stage 15 during the photolithographic operations.

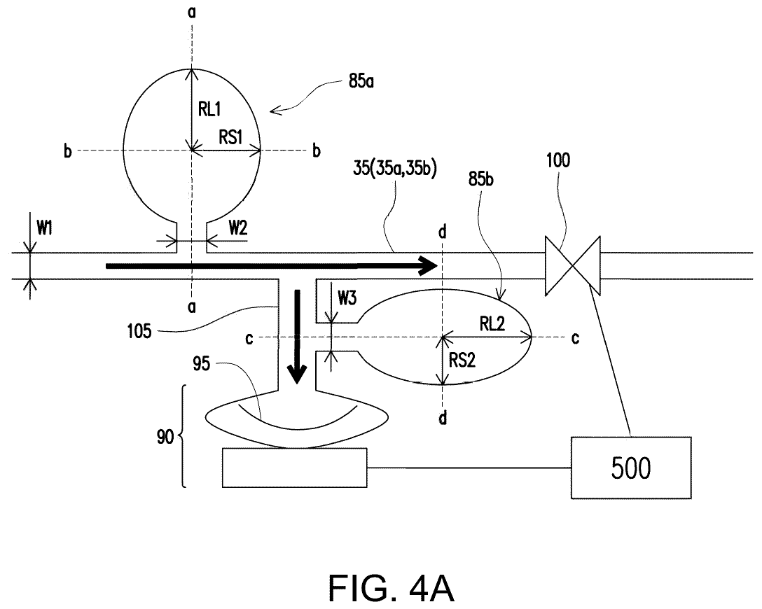

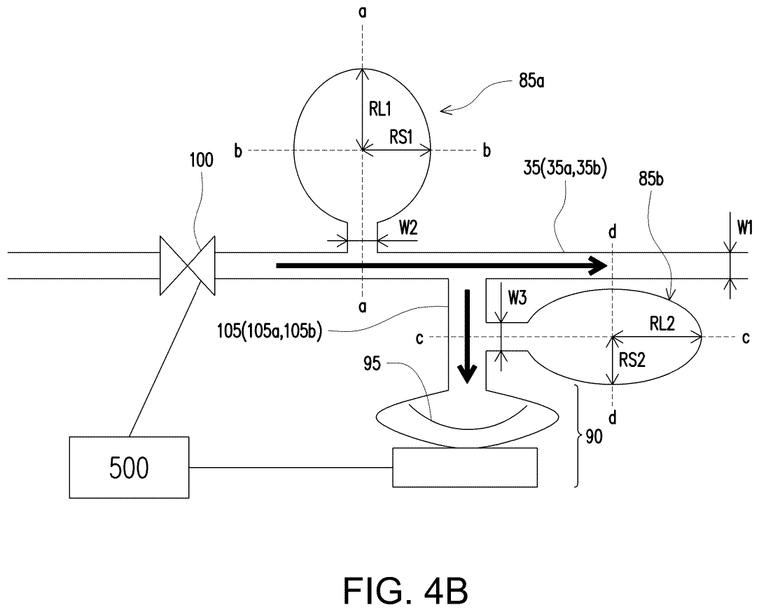

FIGS. 4A and 4B are schematic illustrations of the pressure compensators 20 according to some embodiments of the disclosure. As shown in FIG. 4A, a coolant or cooling fluid line or conduit 35 is arranged along a first direction. The coolant or cooling fluid line or conduit 35 (main line) may be an inflow line 35a to the wafer stage 15 or an outflow line 35b from the wafer stage 15. A pressure sensor line or conduit 105 is connected to the coolant or cooling fluid line or conduit 35. The pressure sensor line or conduit 105 is arranged along a second direction substantially perpendicular to the coolant or cooling fluid line 35, as shown in FIGS. 4A and 4B. The arrows denote the direction of coolant or cooling fluid flow. A pressure sensor 90 is located in the pressure sensor line or conduit 105. The pressure sensor 90 measures the pressure of the coolant or cooling fluid. In some embodiments, the pressure sensor 90 includes a diaphragm 95. In some embodiments, the diaphragm 95 is made of silicon. The pressure sensor 90 determines the cooling fluid or coolant pressure based on the deflection of the diaphragm 95 caused by the cooling fluid or coolant. The thickness of the diaphragm 95 is such that it deflects in response to fluid pressure. However, if the pressure is too high and the deflection of the diaphragm is too much, the diaphragm 95 may be damaged or break. Pressure shock caused by the inertia of the coolant or cooling fluid coupled with the rapid motion and rapid change of directions of the wafer stage 15, or pulsed delivery of coolant or cooling fluid can damage or break the diaphragm 95. A valve 100 is disposed in the coolant or cooling fluid line or conduit (or main line) 35 in some embodiments. A first tank or first vessel 85a is attached to and in fluid communication with the main line 35 and a second tank or second vessel 85b is attached to and in fluid communication the pressure sensor line 105 in some embodiments.

The valve 100 regulates the flow rate and pressure of the coolant or cooling fluid. In some embodiments, the controller 500 monitors the pressure sensor 90 and the controls the opening or closing of the valve 100 in response to the pressure measured by the pressure sensor 90. In some embodiments, the valve 100 is located downstream from the pressure sensor line 105. In some embodiments, the valve 100 is a gate valve, a ball valve, a butterfly valve, a needle valve, a globe valve, a plug valve, a pinch valve, a solenoid valve, or any suitable valve. In some embodiments, the valve 100 is pneumatically or hydraulically activated.

The tanks or vessels 85a, 85b are ellipsoidal in some embodiments. In some embodiments, a first tank or vessel 85a is attached to the main line 35, and a long axis a-a of the first tank 85a is aligned along a direction substantially perpendicular to the first main line 35 (the first direction) and a short axis b-b of the first tank 85a is aligned along a direction substantially parallel to the first main line 35 (the second direction). In some embodiments, a long axis c-c of a second tank or vessel 85b is aligned along a direction substantially perpendicular to the pressure sensor line 105 and a short axis d-d of the second tank or vessel 85b is aligned along a direction substantially parallel to the pressure sensor line 105. In some embodiments, the main line 35 or the pressure sensor line 105 has a diameter or width W1 and the tanks or vessels 85a, 85b have inlets having a diameter or width W2, W3. In some embodiments W1, W2, W3 are about the same (e.g., t5%). In some embodiments, the ellipsoidal tanks or vessels 85a, 85b have a long radius RL1, RL2, respectively, and a short radius RS1, RS2, respectively.

In some embodiments, a relationship between the sizes of the inlet and the tank or vessel 85a, 8b is ¼ (RL1, RL2, RS1, RS2)<W1, W2, W3<½(RL1, RL2, RS1, RS2). In some embodiments, RL1 and RL2 range from about 2 cm to about 20 cm. In other embodiments, RL1 and RL2 range from about 5 cm to about 15 cm. In some embodiments, RS1 and RS2 range from about 1 cm to about 19 cm. In other embodiments, RS1 and RS2 range from about 4 cm to about 14 cm. In some embodiments RL1>RS1 and RL2>RS2. In some embodiments, RL1/RS1 and RL2/RS2 range from about 1.1 to about 20. In other embodiments, RL1/RS1 and RL2/RS2 range from about 1.5 to about 4. Tank or vessel radii greater than these ranges may increase the pressure compensator 20 size and interfere with the photolithographic device functioning. Tank or vessel radii less than the disclosed ranges may provide insufficient buffering capacity of the tank or vessel to prevent the disturbance effect. Ratios of the long tank or vessel radius (RL1, RL2) to the short tank or vessel radius (RS1, RS2) outside of the disclosed ranges may provide insufficient buffering capacity of the tank or vessel to prevent the disturbance effect. In some embodiments, two or more tanks (same size or different sizes) are provided at the main line 35 and the pressure sensor line 105.

In some embodiments, the pressure sensor 90, the first tank or vessel 85a, the second tank or vessel 85b, and the valve 100 are in fluid communication with the inflow line 35a, and a third tank or vessel, a fourth tank or vessel, a second pressure sensor, and a second valve are similarly arranged on the outflow line 35b. In other words, the arrangement shown in FIG. 4A is on both the inflow line 35a and the outflow line 35b in some embodiments.

FIG. 4B depicts another embodiment of the disclosure. FIG. 4B is similar to FIG. 4A, except the valve 100 is located in the main line 35 upstream from the tanks or vessels 85a, 85b. The arrangement shown in FIG. 4B is on both the inflow line 35a and the outflow line 35b in some embodiments. In some embodiments, one of the inflow line 35a and the outflow line 35b includes the tank or vessel, sensor, and valve arrangement shown in FIG. 4A, and the other of the inflow line 35a and the outflow line includes the tank or vessel, sensor, and valve arrangement shown in FIG. 4B.

The pressure of the coolant or cooling fluid flowing through the wafer stage is controlled using the pressure compensator 20. It is desirable to minimize the difference in coolant or cooling fluid pressure in the inflow line 35a and outflow line 35b in the wafer stage 15 to prevent the disturbance effect. The disturbance effect negatively impacts the movement of the wafer stage during wafer exposure. In some embodiments, the pressure compensator 20 incorporating the first and second tanks or vessels 85a, 85b and the control system (controller 500, pressure sensors 90, and valves 100) described herein reduce the pressure difference between the inflow line 35a and the outflow line 35b by about 2 times to about 4 times the pressure difference when the tanks/vessels and control system are not used. It is further desirable to limit the fluid pressure and pressure shocks in both the inflow line 35a and the outflow line 35b to protect the integrity of pressure sensors 90 monitoring the pressure in the coolant flow lines. If the pressure or pressure shock is too high, the fluid pressure may damage the diaphragm 95 in the pressure sensor 90. If the pressure sensors 90 are damaged and not working properly, the pressure compensator's 20 ability to minimize the pressure differences in the inflow line 35a and the outflow line 35b will be hindered. The pressure pulse disturbances may cause instability in the motion of the wafer stage 15, which impacts the accuracy and precision of pattern overlay during the exposure operations. Thus, increased pattern defects and reduced device yield may result. In some embodiments, the pressure compensator 20 incorporating the first and second tanks or vessels 85a, 85b and the control system (controller 500, pressure sensors 90, and valves 100) described herein protect the pressure sensor diaphragm and reduce the disturbance effect. Because the pressure compensator of the present disclosure reduces instability in the motion of the wafer stage 15, the wafer stage 15 can be positioned more accurately during the photolithographic exposure operations. Thus, enhanced pattern overlay is obtained by embodiments of the disclosure resulting in improved device yield.

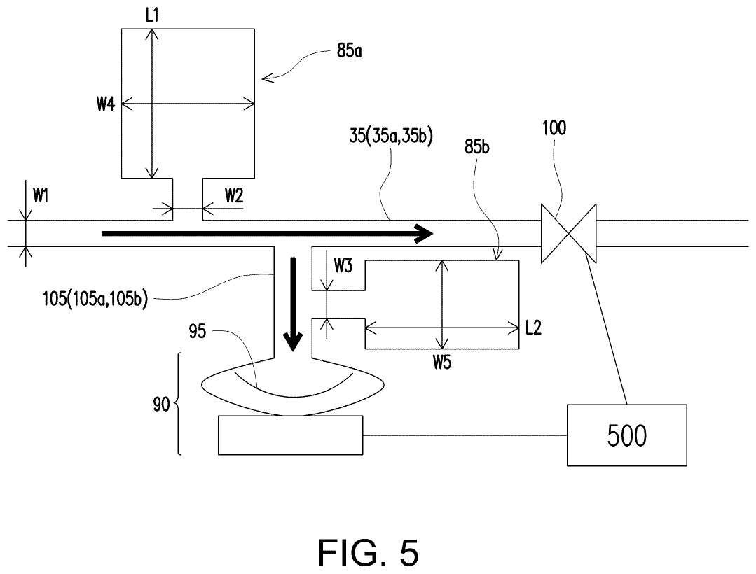

FIG. 5 depicts another embodiment of the disclosure. FIG. 5 is similar to FIG. 4A, except the first tank or vessel 85a and second tank or vessel 85b are rectangular cuboids. The first rectangular cuboid tank or vessel 85a has a length L1 and a width W4, and the second tank or vessel 85b has a length L2 and a width W5. In some embodiments, L1=L2, in other embodiments L1≠L2. In some embodiments, W4=W5, and in other embodiments W4≠W5. The first tank or vessel 85a and the second tank or vessel 85b have a depth equal to their respective widths W4, W5 in some embodiments. The first tank or vessel 85a and the second tank or vessel 85b are located upstream from the valve 100 in some embodiments, as shown in FIG. 5. In other embodiments, the first tank or vessel 85a and the second tank or vessel 85b are located downstream from the valve 100, similar to FIG. 4B. In some embodiments, the pressure sensor 90, the first tank or vessel 85a, the second tank or vessel 85b, and the valve 100 are in fluid communication with the inflow line 35a, and a third tank or vessel, a fourth tank or vessel, a second pressure sensor, and a second valve are similarly arranged on the outflow line 35b. In other words, the arrangement shown in FIG. 5 is on both the inflow line 35a and the outflow line 35b in some embodiments. In some embodiments, one of the inflow line 35a and the outflow line 35b includes the tank or vessel, sensor, and valve arrangement shown in FIG. 5, and the other of the inflow line 35a and the outflow line 35b includes the tanks or vessels and sensor arranged downstream from the valve 100, similar to FIG. 4B. In some embodiments, the main line 35 or the pressure sensor line 105 has a diameter or width W1 and the tanks or vessels 85a, 85b have inlets having a diameter or width W2, W3. In some embodiments W1, W2, W3 are about the same. In some embodiments, a relationship between the sizes of the inlet and the tank or vessel 85a, 8b is ¼ (L1, L2, W4, W5)<W1, W2, W3<½(L1, L2, W4, W5).

In some embodiments, the tanks or vessels 85a, 85b are made of the same material as the main line. In some embodiments, the tanks or vessels 85a, 85b are made of an engineering plastic. In some embodiments, the tanks or vessels 85a, 85b are made of a fluorocarbon polymer, such as polytetrafluoroethylene. In other embodiments, the tanks or vessels 85a, 85b are made of a metal or an alloy, such as stainless steel, copper, or aluminum. The walls of the tanks or vessels 85a, 85b are sufficiently thick and rigid so that the tank or vessel walls do not deflect during operation of the immersion photolithography apparatus.

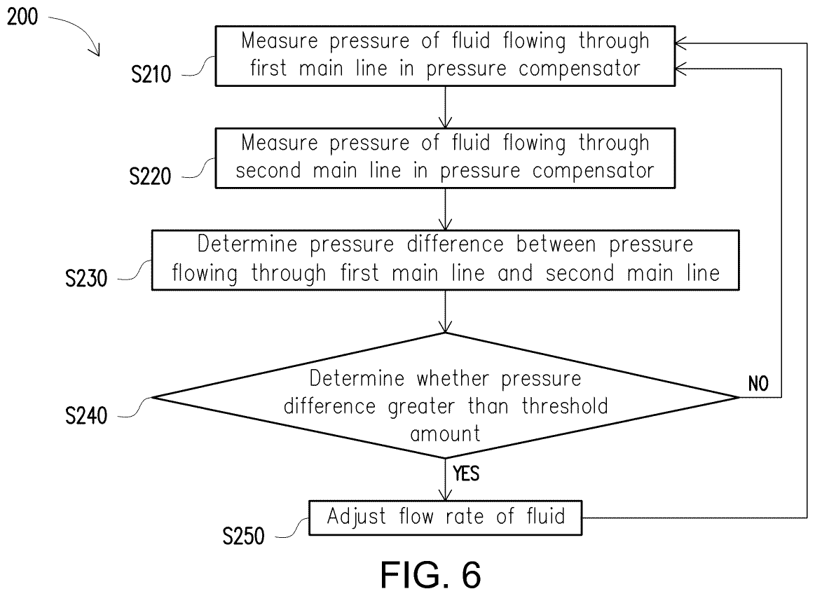

FIG. 6 shows a flowchart of a method of manufacturing a semiconductor device according to some embodiments of the disclosure. As shown in the flowchart of FIG. 6, in some embodiments, a method 200 of manufacturing a semiconductor device includes an operation S210 of measuring a pressure of a fluid flowing through a first main line 35 in a pressure compensator 20 using a first pressure sensor 90. In operation S220, a pressure of the fluid flowing through a second main line 35 in the pressure compensator 20 is measured using a second pressure sensor 90. A pressure difference between the pressure of the fluid flowing through the first main line 35 and the second main line 35 is determined in operation S230. Then in operation S240, whether the pressure difference is greater than a threshold amount is determined. If the pressure difference is greater than a threshold amount, the flow rate of the fluid is adjusted in operation S250. After adjusting the flow rate of the fluid, operations S210-S250 are repeated until it is determined the pressure difference is below the threshold amount. If the pressure difference is below the threshold amount, operations S210-S240 are periodically repeated to ensure the pressure difference is maintained below the threshold amount. In some embodiments, the pressure compensator 20 includes a valve 100 in the first main line 35 or the second main line 35, and the flow rate of the fluid is adjusted by adjusting the valve 100. In some embodiments, the flow rate of the fluid is adjusted so that a difference between the pressure of the fluid in the first main line and the pressure of the fluid in the second main line is 200 Pa or less.

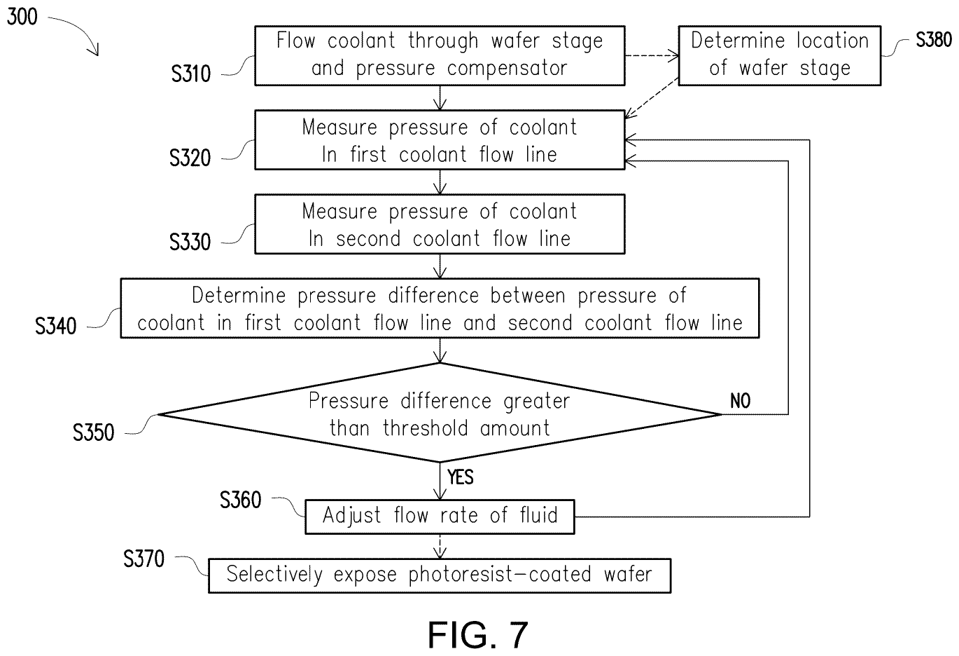

FIG. 7 shows a flowchart of a method of manufacturing a semiconductor device according to some embodiments of the disclosure. As shown in the flowchart of FIG. 7, in some embodiments, a method 300 of manufacturing a semiconductor device includes controlling pattern overlay during photolithographic exposure operations. The method 300 includes an operation S310 of flowing a coolant through a wafer stage 15 that moves a photoresist-coated wafer 25 during the photolithographic exposure operations and through a pressure compensator 20. The pressure compensator includes 20: a first coolant flow line 35, a first valve 100 in the first coolant flow line, a first pressure sensor line 105 intersecting the first coolant flow line 105, a first pressure sensor 90 attached to the first pressure sensor line 105, a first tank 85a in fluid communication with the first coolant flow line 35, a second tank 85b in fluid communication with the first pressure sensor line 105, and a second coolant flow line 35. The coolant flows in an opposite direction relative to the wafer stage in the second coolant flow line from a direction the coolant flows in the first coolant flow line. A pressure of the coolant in the first coolant flow line 35 is measured in operation S320 and a pressure of the coolant in the second coolant flow line 35 is measured in operation S330. Then, in operation S340, a pressure difference between the pressure of the coolant in the first coolant flow line and the pressure of the coolant in the second coolant flow line is determined. Whether the pressure difference is greater than a threshold value is determined in operation S350. If the pressure difference is greater than the threshold amount a flow rate of the coolant is adjusted to bring the pressure difference below the threshold amount in operation S360. After adjusting the flow rate of the coolant, operations S320-S360 are repeated until it is determined the pressure difference is below the threshold amount. If the pressure difference is less than the threshold amount operations S320-S350 are repeated periodically to ensure the pressure difference is maintained below the threshold amount.

In some embodiments, the method includes an operation S370 of selectively exposing the photoresist-coated wafer 25 to actinic radiation. In some embodiments, a location of the wafer stage 15 during the photolithographic exposure operations is determined in operation S380.

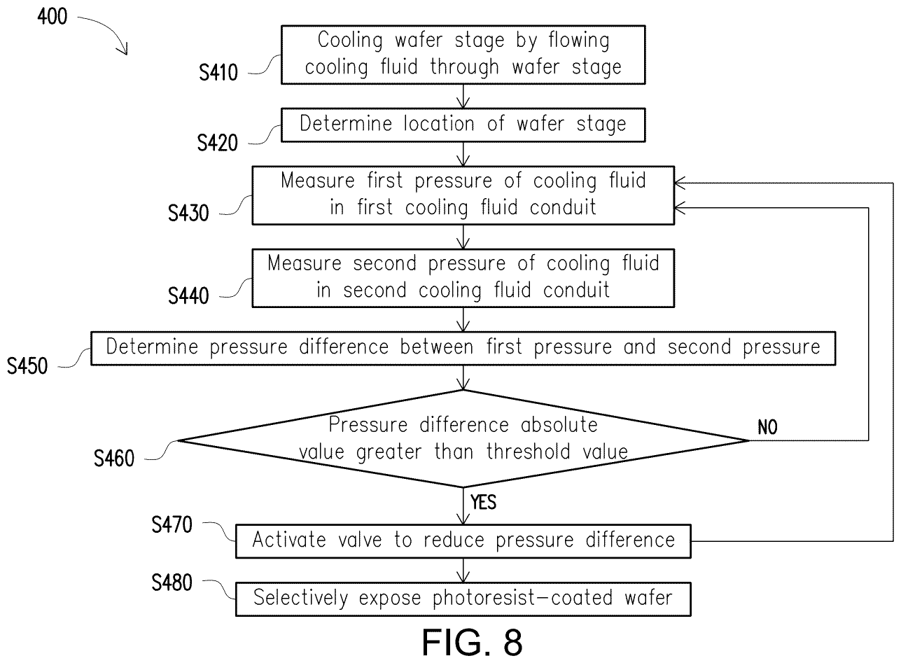

FIG. 8 shows a flowchart of a method of manufacturing a semiconductor device according to some embodiments of the disclosure. As shown in FIG. 8, in some embodiments, a method 400 includes an operation S410 of cooling a wafer stage 15 that moves a photoresist coated wafer 25 during a photolithographic operation by flowing cooling fluid through the wafer stage 15. A location of the wafer stage 15 is determined during the photolithographic operation in operation S420. A first pressure of the cooling fluid flowing along a first direction in a first cooling fluid conduit 35 is measured using a first pressure sensor 90 in operation S430. The first pressure sensor 90 is located in a first pressure sensor conduit 105 oriented in a second direction perpendicular to the first direction. A first vessel 85a is oriented along the second direction, the first vessel 85a having a first inlet in the first cooling flow conduit 85, and a second vessel 85b is oriented along the first direction, the second vessel 85b having a second inlet in the first pressure sensor conduit 105. A second pressure of the cooling fluid flowing along a third direction in a second cooling fluid conduit 105 is measured using a second pressure sensor 90 in operation S440. The third direction is opposite to the first direction. The second pressure sensor 90 is located in a second pressure sensor conduit 105 oriented in a fourth direction perpendicular to the second direction. Then, in operation S450, a pressure difference between the first pressure and the second pressure is determined. Whether an absolute value of the pressure difference is greater than a threshold value is determined in operation S460. If the absolute value of the pressure difference is greater than the threshold value a valve 100 in the first cooling fluid conduit 105 or second cooling fluid conduit 105 is activated in operation S470. After the valve is activated, operations S430-S470 are repeated until it is determined the pressure difference is below the threshold value. If the absolute value of the pressure difference is less than the threshold value operations S430-S460 are periodically repeated to ensure the pressure difference is maintained below the threshold amount. The photoresist coated wafer 25 is selectively exposed to actinic radiation in operation S480.

In some embodiments, the threshold value is 200 Pa or less. In some embodiments, a third vessel 85a is oriented along the fourth direction and the third vessel 85a has a third inlet in the second cooling fluid conduit 105, and a fourth vessel 85b is oriented along the third direction and has a fourth inlet in the second pressure sensor conduit 105.

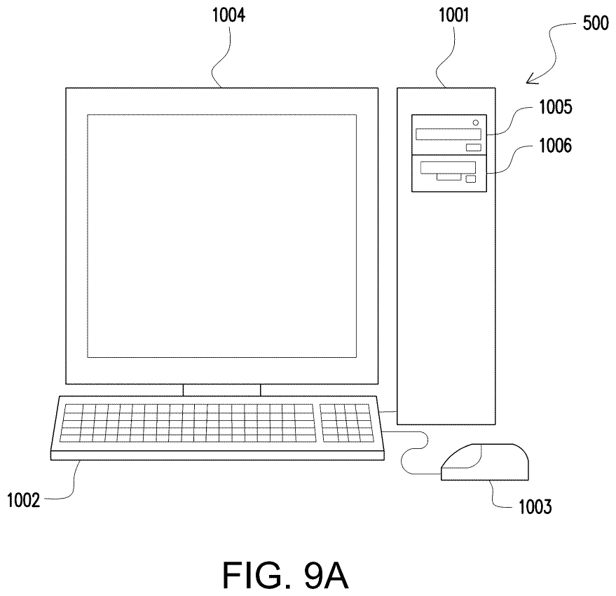

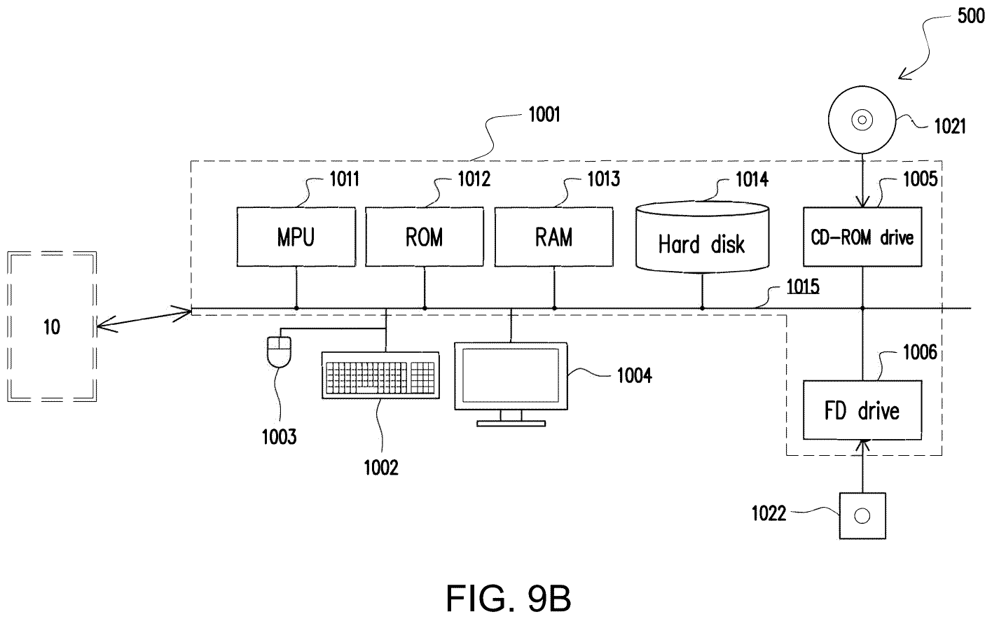

In some embodiments, the controller 500 is a computer system. FIG. 9A and FIG. 9B illustrate a computer system 500 for controlling an immersion photolithography apparatus 10 its components in accordance with various embodiments of the disclosure. FIG. 9A is a schematic view of the computer system 500 that controls the immersion photolithography apparatus 10 and its components of FIGS. 1-5. In some embodiments, the computer system 500 is programmed to measure the pressure using the pressure sensors 90, determine the pressure difference, determine whether the pressure difference is greater than a threshold pressure difference stored in the computer system 500, and adjust a valve 100 to change a flowrate of a coolant or cooling fluid, to reduce the pressure difference to below the threshold pressure difference.

As shown in FIG. 9A, the computer system 500 is provided with a computer 1001 including an optical disk read only memory (e.g., CD-ROM or DVD-ROM) drive 1005 and a magnetic disk drive 1006, a keyboard 1002, a mouse 1003 (or other similar input device), and a monitor 1004 in some embodiments.

FIG. 9B is a diagram showing an internal configuration of the computer system 500. In FIG. 9B, the computer 1001 is provided with, in addition to the optical disk drive 1005 and the magnetic disk drive 1006, one or more processors 1011, such as a micro-processor unit (MP) or a central processing unit (CPU); a read-only memory (ROM) 1012 in which a program, such as a boot up program is stored; a random access memory (RAM) 1013 that is connected to the processors 1011 and in which a command of an application program is temporarily stored, and a temporary electronic storage area is provided; a hard disk 1014 in which an application program, an operating system program, and data are stored; and a data communication bus 1015 that connects the processors 1011, the ROM 1012, and the like. Note that the computer 1001 may include a network card (not shown) for providing a connection to a computer network such as a local area network (LAN), wide area network (WAN) or any other useful computer network for communicating data used by the computer system 500 and the immersion photolithography apparatus 10. In various embodiments, the controller 500 communicates via wireless or hardwired connection to the immersion photolithography apparatus 10 and its components.

The programs for causing the computer system 500 to execute the method for controlling immersion photolithography apparatus 10 and the pressure compensator 20 of FIGS. 1-3 and 4A-5 are stored in an optical disk 1021 or a magnetic disk 1022, which is inserted into the optical disk drive 1005 or the magnetic disk drive 1006, and transmitted to the hard disk 1014. Alternatively, the programs are transmitted via a network (not shown) to the computer system 500 and stored in the hard disk 1014. At the time of execution, the programs are loaded into the RAM 1013. The programs are loaded from the optical disk 1021 or the magnetic disk 1022, or directly from a network in various embodiments.

The stored programs do not necessarily have to include, for example, an operating system (OS) or a third-party program to cause the computer 1001 to execute the methods disclosed herein. The program may only include a command portion to call an appropriate function (module) in a controlled mode and obtain desired results in some embodiments. In various embodiments described herein, the controller 500 is in communication with the immersion photolithography apparatus 10 to control various functions thereof.

The controller 500 is coupled to the immersion photolithography apparatus 10 including the pressure compensator 20 in various embodiments. The controller 500 is configured to provide control data to those system components and receive process and/or status data from those system components. For example, in some embodiments, the controller 500 comprises a microprocessor, a memory (e.g., volatile or non-volatile memory), and a digital I/O port capable of generating control voltages sufficient to communicate and activate inputs to the processing system, as well as monitor outputs from the immersion photolithography apparatus 10. In addition, a program stored in the memory is utilized to control the aforementioned components of the immersion photolithography apparatus 10 according to a process recipe. Furthermore, the controller 500 is configured to analyze the process and/or status data, to compare the process and/or status data with target process and/or status data, and to use the comparison to change a process and/or control a system component. In addition, the controller 500 is configured to analyze the process and/or status data, to compare the process and/or status data with historical process and/or status data, and to use the comparison to predict, prevent, and/or declare a fault or alarm.

As set forth above, the executed program causes the processor or computer 500 to measure the pressure in the coolant or cooling fluid line or conduit, determine a pressure difference between the coolant or cooling fluid inflow line and outflow line, determine whether the pressure difference is greater than a threshold value, and adjust a valve to change the coolant or cooling fluid flowrate to reduce the pressure difference when the pressure difference is greater than the stored threshold value. In some embodiments, the executed program causes the processor or computer 500 to measure the pressure in the coolant or cooling fluid line or conduit periodically, for example, every second, 10 seconds, 20 seconds, or 30 seconds.

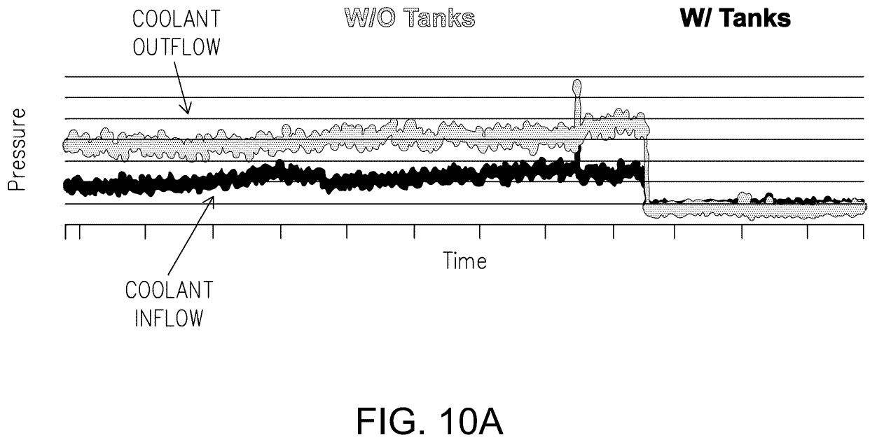

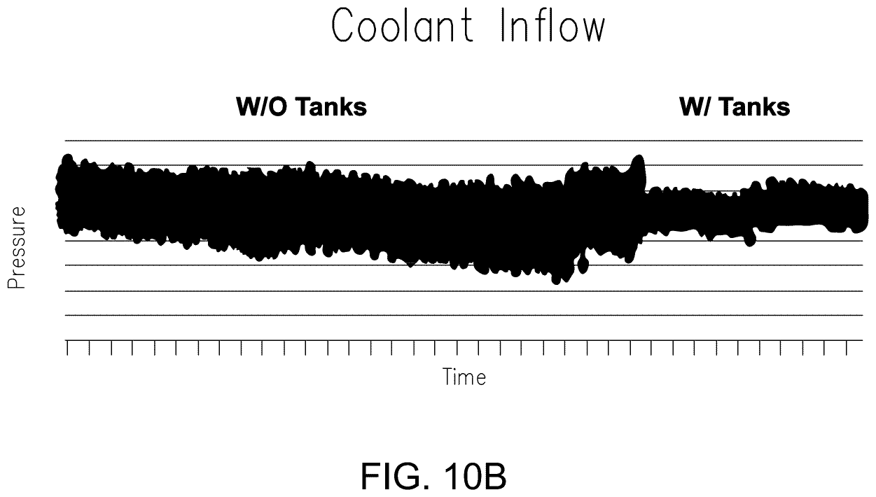

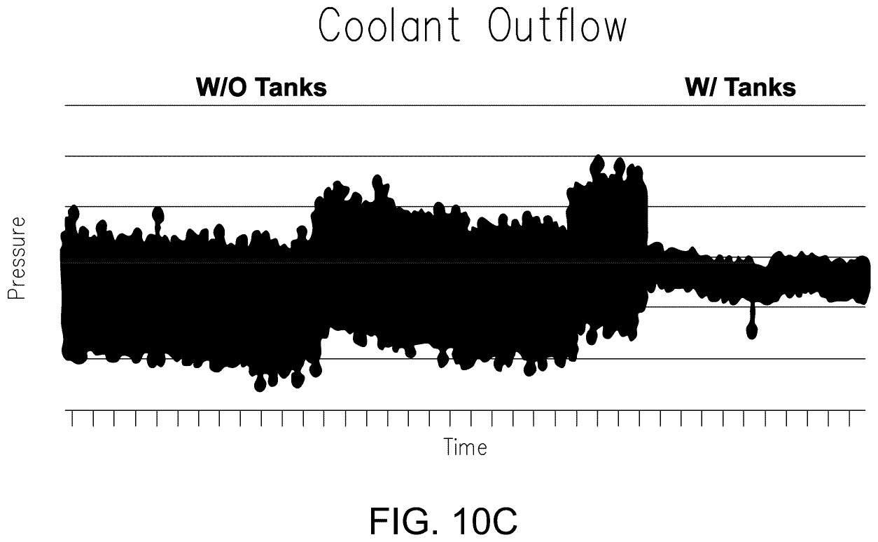

FIG. 10A shows the difference between the standard deviation of the incoming coolant fluid pressure and the standard deviation of the outgoing cooling fluid pressure in the pressure compensator according to some embodiments of the disclosure. As shown in FIG. 10A, there is a large difference between the pressure of the coolant or cooling fluid in the inflow line 35a and the outflow line 35b when the pressure compensator 20 does not include the first and second tanks or vessels 85a, 85b. When the pressure compensator 20 includes the tanks or vessels 85a, 85b and the control system (pressure sensors, controller, and valves) described herein the pressure difference between the inflow line 35a and outflow line 35b is significantly reduced.

FIG. 10B shows the variation in the pressure of the coolant or cooling fluid in the inflow line 35a in the pressure compensator 20 in some embodiments. When the pressure compensator 20 includes the tanks or vessels 85a, 85b and the control system (pressure sensors, controller, and valves) described herein the pressure variation in the inflow line 35a is significantly reduced during the immersion photolithography apparatus 10 operation.

FIG. 10C shows the variation in the pressure of the coolant or cooling fluid in the outflow line 35b in the pressure compensator 20 in some embodiments. When the pressure compensator 20 includes the tanks or vessels 85a, 85b and the control system (pressure sensors, controller, and valves) described herein the pressure variation in the outflow line 35b is significantly reduced during the immersion photolithography apparatus 10 operation.

In some embodiments, the methods disclosed herein include methods of operating a lithography tool, and methods of enhancing pattern overlay.

The coolant pressure compensation or stabilization techniques as explained above can be applied to any movable wafer stages that require temperature control by fluid. In some embodiments, the stage is for an extreme ultraviolet (EUV) lithography scanner, or a DUV lithography scanner without using the immersion technique. The lithography tool may be an electron beam lithography apparatus for a photomask fabrication. In other embodiments, the wafer stage is for an etching apparatus, a film deposition apparatus, or a measurement apparatus used in a semiconductor device manufacturing process.

Other embodiments include other operations before, during, or after the operations described above. In some embodiments, the disclosed methods include forming fin field effect transistor (FinFET) structures. In some embodiments, a plurality of active fins is formed on the wafer. Such embodiments, further include etching the wafer through the openings of a patterned hard mask to form trenches in the wafer; filling the trenches with a dielectric material; performing a chemical mechanical polishing (CMP) process to form shallow trench isolation (SIT) features; and epitaxy growing or recessing the STI features to form fin-like active regions. In some embodiments, one or more gate electrodes are formed on the wafer. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the wafer, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, other three-dimensional (3D) FETs, and other memory cells are formed on the wafer.

As semiconductor devices become smaller, layer to layer overlay becomes more important due to the small process window. Embodiments of the present disclosure protect the pressure sensor diaphragm and reduce the disturbance effect. Embodiments of the present disclosure enhance pattern overlay and improved device yield. In some embodiments, the apparatus and methods disclosed herein provide about a 2 times to about 4 times reduction in the pressure difference between the coolant or cooling fluid in the inflow line 35a and the outflow line 35b of the pressure compensator.

It will be understood that not all advantages have been necessarily discussed herein, no particular advantage is required for all embodiments or examples, and other embodiments or examples may offer different advantages.

In an embodiment of the disclosure, a method of manufacturing a semiconductor device includes measuring a pressure of a fluid flowing through a first main line in a pressure compensator using a first pressure sensor. The fluid flows along the first main line through the pressure compensator to a semiconductor device processing apparatus, through the semiconductor device processing apparatus, and then back through the pressure compensator via a second main line. The first pressure sensor is attached to a first pressure sensor line branching off the first main line. A pressure of the fluid flowing through the second main line is measured using a second pressure sensor. The second pressure sensor is attached to a second pressure sensor line branching off the second main line. A pressure difference between the pressure of the fluid flowing through the first main line and the second main line is determined. Whether the pressure difference is greater than a threshold amount is determined. A flow rate of the fluid is adjusted when the pressure difference is greater than the threshold amount. A first tank is attached to one of the first main line or the second main line via a first conduit, and a second tank is attached to the first pressure sensor line when the first tank is attached to the first main line or is attached the second pressure sensor line when the first tank is attached to the second main line via a second conduit. In an embodiment, the first tank is attached to the first main line, and a long axis or a length of the first tank is aligned along a direction perpendicular to the first main line and a short axis or a width of the first tank is aligned along a direction parallel to the first main line. In an embodiment, a long axis or a length of the second tank is aligned along a direction perpendicular to the first pressure sensor line and a short axis or a width of the second tank is aligned along a direction parallel to the first pressure sensor line. In an embodiment, the pressure compensator includes a valve in the first main line or the second main line, and the flow rate of the fluid is adjusted by adjusting the valve. In an embodiment, the first tank is attached to the first main line, and the first tank and the second tank are upstream from the first pressure sensor along a direction of the fluid flow. In an embodiment, the first tank is attached to the first main line, the second tank is attached to the first pressure sensor line, a third tank is attached to the second main line, and a fourth tank is attached to the second pressure sensor line. In an embodiment, a long axis or a length of the third tank is aligned along a direction perpendicular to the second main line and a short axis or a width of the third tank is aligned along a direction parallel to the second main line, and a long axis or a length of the fourth tank is aligned along a direction perpendicular to the second pressure sensor line and a short axis or a width of the fourth tank is aligned along a direction parallel to the second pressure sensor line. In an embodiment, the flow rate of the fluid is adjusted so that a difference between the pressure of the fluid in the first main line and the pressure of the fluid in the second main line is 200 Pa or less.

In another embodiment of the disclosure, a method of manufacturing a semiconductor device includes controlling pattern overlay during photolithographic exposure operations. The method includes flowing a coolant through a wafer stage that moves a photoresist-coated wafer during the photolithographic exposure operations and through a pressure compensator. The pressure compensator includes: a first coolant flow line, a first valve in the first coolant flow line, a first pressure sensor line intersecting the first coolant flow line, a first pressure sensor attached to the first pressure sensor line, a first tank in fluid communication with the first coolant flow line, a second tank in fluid communication with the first pressure sensor line, and a second coolant flow line. The coolant flows in an opposite direction relative to the wafer stage in the second coolant flow line from a direction the coolant flows in the first coolant flow line. A pressure of the coolant in the first coolant flow line is measured. A pressure of the coolant in the second coolant flow line is measured. A pressure difference between the pressure of the coolant in the first coolant flow line and the pressure of the coolant in the second coolant flow line is determined. When the pressure difference is greater than a threshold value a flow rate of the coolant is adjusted to bring the pressure difference below the threshold value. In an embodiment, the method includes selectively exposing the photoresist-coated wafer to actinic radiation. In an embodiment, a long axis or a length of the first tank is aligned along a direction perpendicular to the first coolant flow line and a short axis or a width of the first tank is aligned along a direction parallel to the first coolant flow line. In an embodiment, a long axis or a length of the second tank is aligned along a direction perpendicular to the first pressure sensor line and a short axis or a width of the second tank is aligned along a direction parallel to the first pressure sensor line. In an embodiment, the pressure compensator includes a valve in the first coolant flow line or the second coolant flow line, and the flow rate of the coolant is adjusted by adjusting the valve. In an embodiment, the first tank and second tank are upstream from the first pressure sensor along a direction of the coolant flow. In an embodiment, the pressure compensator further includes: a second pressure sensor line intersecting the second coolant flow line, a second pressure sensor attached to the second pressure sensor line, a third tank in fluid communication with the second coolant flow line, and a fourth tank in fluid communication with the second pressure sensor line. In an embodiment, a long axis or a length of the third tank is aligned along a direction perpendicular to the second coolant flow line and a short axis or a width of the third tank is aligned along a direction parallel to the second coolant flow line, and a long axis or a length of the fourth tank is aligned along a direction perpendicular to the second pressure sensor line and a short axis or a width of the fourth tank is aligned along a direction parallel to the second pressure sensor line. In an embodiment, a location of the wafer stage during the photolithographic exposure operations is determined.

In another embodiment of the disclosure, a method includes cooling a wafer stage that moves a photoresist coated wafer during a photolithographic operation by flowing a cooling fluid through the wafer stage. A location of the wafer stage is determined during the photolithographic operation. A first pressure of the cooling fluid flowing along a first direction in a first cooling fluid conduit is measured using a first pressure sensor. The first pressure sensor is located in a first pressure sensor conduit oriented in a second direction perpendicular to the first direction. A first vessel is oriented along the second direction, the first vessel having a first inlet in the first cooling flow conduit, and a second vessel is oriented along the first direction, the second vessel having a second inlet in the first pressure sensor conduit. A second pressure of the cooling fluid flowing along a third direction in a second cooling fluid conduit is measured using a second pressure sensor. The third direction is opposite to the first direction. The second pressure sensor is located in a second pressure sensor conduit oriented in a fourth direction perpendicular to the second direction. A pressure difference between the first pressure and the second pressure is determined. Whether an absolute value of the pressure difference is greater than a threshold value is determined. A valve in the first cooling fluid conduit or second cooling fluid conduit is activated when the absolute value of the pressure difference is greater than the threshold value to reduce the pressure difference to less than the threshold value. The photoresist coated wafer is selectively exposed to actinic radiation. In an embodiment, the threshold value is 200 Pa or less In an embodiment, a radius of the first inlet is greater than one fourth of a radius of a short axis or half width of the first vessel and less than one half of a long axis or half length of the first vessel, and a radius of the second inlet is greater than one fourth of a radius of a short axis or half width of the second vessel and less than one half of a long axis or half length of the second vessel. In an embodiment, a third vessel is oriented along the fourth direction and the third vessel has a third inlet in the second cooling fluid conduit, and a fourth vessel is oriented along the third direction and has a fourth inlet in the second pressure sensor conduit.

In another embodiment of the disclosure, an apparatus, includes a semiconductor device processing device having a coolant flow conduit and a pressure compensator. The pressure compensator includes an inlet flow conduit arranged in a first direction in fluid communication with the coolant flow conduit, an outlet flow conduit arranged in a parallel direction to the first direction in fluid communication with the coolant flow conduit, a first pressure sensor conduit attached to the inlet flow conduit and arranged in a second direction perpendicular to the first direction, a first pressure sensor in the first pressure sensor conduit, a second pressure sensor conduit attached to the outlet flow conduit and arranged in the second direction, a second pressure sensor in the second pressure sensor conduit, and a first tank in fluid communication with the inlet flow conduit or outlet flow conduit. A long axis or length of the first tank is oriented along the second direction. A second tank is in fluid communication with the first pressure sensor conduit or second pressure sensor conduit. A long axis of the second tank is oriented along the first direction, and a valve is in fluid communication with the inlet flow conduit or the outlet flow conduit. In an embodiment, the semiconductor device processing device is a movable wafer stage. In an embodiment, the first tank is in fluid communication with the inlet flow conduit and the second tank is in fluid communication with the first pressure sensor conduit. In an embodiment, the apparatus includes a third tank in fluid communication with the outlet flow conduit, wherein a long axis or length of the third tank is oriented along the second direction; and a fourth tank in fluid communication with the second pressure sensor conduit, wherein a long axis of the second tank is oriented along the first direction. In an embodiment, the first tank has a first inlet, and a diameter of the first inlet is less than half a short axis or half a width of the first tank; and the second tank has a second inlet, and a diameter of the second inlet is less than half a short axis or half a width of the second tank. In an embodiment, the first tank and second tank are ellipsoidal. In an embodiment, the first tank and the second tank are rectangular cuboids. In an embodiment, the apparatus includes an interferometer; and a controller configured to: control the interferometer; determine a location of the movable wafer stage using the interferometer; control the first pressure sensor and the second pressure sensor; determine a difference in pressure measured by the first pressure sensor and the second pressure sensor; determine whether the difference in pressure is greater than a threshold value; and adjust the valve to adjust a flow rate of a coolant so that the difference in pressure is less than the threshold value.

In another embodiment of the disclosure, an apparatus includes semiconductor device processing device having a first coolant flow conduit and a pressure compensator. The pressure compensator includes a second coolant flow conduit arranged in a first direction and in fluid communication with the first fluid flow conduit, a first pressure sensor conduit attached to the second coolant flow conduit and arranged in a second direction perpendicular to the first direction, a first pressure sensor in the first pressure sensor conduit, a first tank oriented along the second direction in fluid communication with the second coolant flow conduit, a second tank oriented along the first direction in fluid communication with the first pressure sensor conduit, a valve in fluid communication with the second coolant flow conduit, and a third coolant flow conduit arranged in a third direction and in fluid communication with the first coolant flow conduit. The second coolant flow conduit, the first coolant flow conduit, and the third coolant flow conduit form a continuous coolant fluid flow path in this order. A second pressure sensor conduit is attached to the third coolant flow conduit and arranged in a fourth direction perpendicular to the third direction, a second pressure sensor in the second pressure sensor conduit. In an embodiment, the apparatus includes a third tank oriented along the fourth direction in fluid communication with the third coolant flow conduit, and a fourth tank oriented along the third direction in fluid communication with the second pressure sensor conduit. In an embodiment, the semiconductor device processing device is wafer stage. In an embodiment, the apparatus includes a controller configured to: control movement of the wafer stage, determine a location of the wafer stage, receive pressure data from the first pressure sensor and the second pressure sensor, determine a difference in pressure measured by the first pressure sensor and the second pressure sensor, determine whether the difference in pressure is greater than a threshold value, and adjust the valve to adjust a flow rate of a coolant so that the difference in pressure is less than the threshold value. In an embodiment, the apparatus includes a second valve in fluid communication with the third coolant flow conduit. In an embodiment, the first tank and the second tank are ellipsoidal or rectangular cuboids.

In another embodiment of the disclosure, a photolithography apparatus includes a movable wafer stage with a first cooling fluid conduit, and a pressure compensator with a second cooling fluid conduit and a third cooling fluid conduit. The first cooling fluid conduit is connected to the second cooling fluid conduit and the third cooling fluid conduit. The pressure compensator includes: a first pressure sensor in fluid communication with the second cooling fluid conduit, a valve in fluid communication with the second cooling fluid conduit, a first vessel in fluid communication with the second cooling fluid conduit adjacent to the first pressure sensor, and a second vessel in fluid communication with the second cooling fluid conduit. The first vessel is further away from the first sensor than the second vessel. A long axis or length of the first vessel is aligned along a first direction and a long axis or length of the second vessel is aligned along a second direction, and the second direction is perpendicular to the first direction. A second pressure sensor is in fluid communication with the third cooling fluid conduit. In an embodiment, the photolithography apparatus includes a second valve in fluid communication with the third cooling fluid conduit. In an embodiment, the photolithography apparatus is an immersion photolithography apparatus. In an embodiment, the photolithography apparatus includes: a third vessel oriented along a third direction in fluid communication with the third cooling fluid conduit and a fourth vessel oriented along a fourth direction in fluid communication with the third cooling fluid conduit, wherein the fourth direction is perpendicular to the third direction. In an embodiment, the photolithography apparatus includes a controller configured to: control movement of the movable wafer stage, determine a location of the movable wafer stage, receive pressure data from the first pressure sensor and the second pressure sensor, determine a difference in pressure measured by the first pressure sensor and the second pressure sensor, determine whether the difference in pressure is greater than a threshold value, and adjust the valve to adjust a flow rate of a cooling fluid so that the difference in pressure is less than the threshold value. In an embodiment, the first vessel and the second vessel are ellipsoidal or rectangular cuboids.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
measuring a pressure of a fluid flowing through a first main line in a pressure compensator using a first pressure sensor,
wherein the fluid flows along the first main line through the pressure compensator to a semiconductor device processing apparatus, through the semiconductor device processing apparatus, and then back through the pressure compensator via a second main line, and
the first pressure sensor is attached to a first pressure sensor line branching off the first main line;
measuring a pressure of the fluid flowing through the second main line using a second pressure sensor,
wherein the second pressure sensor is attached to a second pressure sensor line branching off the second main line;
determining a pressure difference between the pressure of the fluid flowing through the first main line and the second main line;
determining whether the pressure difference is greater than a threshold amount; and
adjusting a flow rate of the fluid when the pressure difference is greater than the threshold amount,
wherein a first tank is attached to one of the first main line or the second main line via a first conduit, and
a second tank is attached to the first pressure sensor line when the first tank is attached to the first main line or is attached the second pressure sensor line when the first tank is attached to the second main line via a second conduit.

2. The method according to claim 1, wherein the first tank is attached to the first main line, and a long axis or a length of the first tank is aligned along a direction perpendicular to the first main line and a short axis or a width of the first tank is aligned along a direction parallel to the first main line.

3. The method according to claim 2, wherein a long axis or a length of the second tank is aligned along a direction perpendicular to the first pressure sensor line and a short axis or a width of the second tank is aligned along a direction parallel to the first pressure sensor line.

4. The method according to claim 1, wherein the pressure compensator includes a valve in the first main line or the second main line, and the flow rate of the fluid is adjusted by adjusting the valve.

5. The method according to claim 1, wherein the first tank is attached to the first main line, and the first tank and the second tank are upstream from the first pressure sensor along a direction of the fluid flow.

6. The method according to claim 1, wherein the first tank is attached to the first main line,
the second tank is attached to the first pressure sensor line,
a third tank is attached to the second main line, and
a fourth tank is attached to the second pressure sensor line.

7. The method according to claim 6, wherein:
a long axis or a length of the third tank is aligned along a direction perpendicular to the second main line and a short axis or a width of the third tank is aligned along a direction parallel to the second main line, and
a long axis or a length of the fourth tank is aligned along a direction perpendicular to the second pressure sensor line and a short axis or a width of the fourth tank is aligned along a direction parallel to the second pressure sensor line.

8. The method according to claim 1, wherein the flow rate of the fluid is adjusted so that a difference between the pressure of the fluid in the first main line and the pressure of the fluid in the second main line is 200 Pa or less.

9. A method of manufacturing a semiconductor device, comprising:
controlling pattern overlay during photolithographic exposure operations, comprising:
flowing a coolant through a wafer stage that moves a photoresist-coated wafer
during the photolithographic exposure operations and through a pressure compensator,
wherein the pressure compensator comprises:
a first coolant flow line,
a first valve in the first coolant flow line,
a first pressure sensor line intersecting the first coolant flow line,
a first pressure sensor attached to the first pressure sensor line,
a first tank in fluid communication with the first coolant flow line,
a second tank in fluid communication with the first pressure sensor line, and
a second coolant flow line,
wherein the coolant flows in an opposite direction relative to the wafer stage in the second coolant flow line from a direction the coolant flows in the first coolant flow line;
measuring a pressure of the coolant in the first coolant flow line;
measuring a pressure of the coolant in the second coolant flow line;
determining a pressure difference between the pressure of the coolant in the first coolant flow line and the pressure of the coolant in the second coolant flow line; and
when the pressure difference is greater than a threshold value adjusting a flow rate of the coolant to bring the pressure difference below the threshold value.

10. The method according to claim 9, further comprising selectively exposing the photoresist-coated wafer to actinic radiation.

11. The method according to claim 9, wherein a long axis or a length of the first tank is aligned along a direction perpendicular to the first coolant flow line and a short axis or a width of the first tank is aligned along a direction parallel to the first coolant flow line.

12. The method according to claim 11, wherein a long axis or a length of the second tank is aligned along a direction perpendicular to the first pressure sensor line and a short axis or a width of the second tank is aligned along a direction parallel to the first pressure sensor line.

13. The method according to claim 9, wherein the pressure compensator includes a valve in the first coolant flow line or the second coolant flow line, and the flow rate of the coolant is adjusted by adjusting the valve.

14. The method according to claim 9, wherein the first tank and second tank are upstream from the first pressure sensor along a direction of the coolant flow.

15. The method according to claim 9, wherein the pressure compensator further comprises:
a second pressure sensor line intersecting the second coolant flow line;
a second pressure sensor attached to the second pressure sensor line;
a third tank in fluid communication with the second coolant flow line; and
a fourth tank in fluid communication with the second pressure sensor line.

16. The method according to claim 15, wherein:
a long axis or a length of the third tank is aligned along a direction perpendicular to the second coolant flow line and a short axis or a width of the third tank is aligned along a direction parallel to the second coolant flow line, and
a long axis or a length of the fourth tank is aligned along a direction perpendicular to the second pressure sensor line and a short axis or a width of the fourth tank is aligned along a direction parallel to the second pressure sensor line.

17. An apparatus, comprising:
a semiconductor device processing device having a coolant flow conduit; and
a pressure compensator, comprising:
an inlet flow conduit arranged in a first direction in fluid communication with the coolant flow conduit;
an outlet flow conduit arranged in a parallel direction to the first direction in fluid communication with the coolant flow conduit;
a first pressure sensor conduit attached to the inlet flow conduit and arranged in a second direction perpendicular to the first direction;
a first pressure sensor in the first pressure sensor conduit;
a second pressure sensor conduit attached to the outlet flow conduit and arranged in the second direction;
a second pressure sensor in the second pressure sensor conduit;
a first tank in fluid communication with the inlet flow conduit or outlet flow conduit,
wherein a long axis or length of the first tank is oriented along the second direction;
a second tank in fluid communication with the first pressure sensor conduit or second pressure sensor conduit,
wherein a long axis of the second tank is oriented along the first direction; and
a valve in fluid communication with the inlet flow conduit or the outlet flow conduit.

18. The apparatus of claim 17, wherein the semiconductor device processing device is a movable wafer stage.

19. The apparatus of claim 17, wherein the first tank is in fluid communication with the inlet flow conduit and the second tank is in fluid communication with the first pressure sensor conduit.

20. The apparatus of claim 19, further comprising:
a third tank in fluid communication with the outlet flow conduit,
wherein a long axis or length of the third tank is oriented along the second direction; and
a fourth tank in fluid communication with the second pressure sensor conduit,
wherein a long axis of the second tank is oriented along the first direction.
